(19) United States
(12) Patent Application Publication
(10) Pub. No.: US 2024/0180001 A1
(43) Pub. Date: May 30, 2024

(54) DISPLAY APPARATUS

(71) Applicant: LG Display Co., Ltd., Seoul (KR)

(72) Inventors: SoJung PARK, Daegu (KR); Ji Eun LEE, Paju-si (KR); Heeyeon HWANG, Hanam-si (KR); SangHoon OH, Buan-gun (KR); Minwan KIM, Paju-si (KR)

(21) Appl. No.: 18/362,542

(22) Filed: Jul. 31, 2023

(30) Foreign Application Priority Data
Nov. 14, 2022 (KR) 10-2022-0151961

(51) Int. Cl. H10K 59/80; H10K 59/40

(52) U.S. Cl. CPC H10K 59/873; H10K 59/40; H10K 59/12

(57) ABSTRACT

The display apparatus may include a display panel including a variable area and a non-variable area, a first adhesive member disposed on the display panel, and a first layer disposed on the first adhesive member, a material of the first layer being different from a material of the first adhesive member. The first layer may include a photoreactive material.

### CROSS-REFERENCE TO RELATED APPLICATIONS

This application claims the priority of Korean Patent Application No. 10-2022-0151961 filed on Nov. 14, 2022, in the Korean Intellectual Property Office, the entirety of which is incorporated herein by reference for all purposes as if fully set forth herein.

### BACKGROUND

### Technical Field

The present disclosure relates to a display apparatus.

### Description of the Related Art

As society entered the full-fledged information age, various display apparatuses which process and display large amounts of information have been developed. As display apparatus which display images, there are various types of display apparatus such as a liquid crystal display apparatus, an organic light emitting display apparatus, and an electrophoretic display apparatus.

Users who watch broadcasts or videos or play video games through a display apparatus prefer a portable display apparatus with a large screen. However, if the screen of the portable display apparatus is enlarged, the portability is degraded so that there is a limit to configuring a large screen. To satisfy both the large-screen size and the portability, studies about a foldable display apparatus in which a display panel is folded and unfolded are being actively conducted.

### BRIEF SUMMARY

When the display apparatus is bent or folded, marks or creases may occur on the folded portion. However, the marks or creases occurring on a folded portion are recognized by a user who uses the display apparatus and may cause inconvenience to the user or degradation of the visibility and the touching sense.

Accordingly, the inventors of the present disclosure recognized the above problems or limitations and conducted various researches and experiments to reduce a distortion caused on the folded portion when the display apparatus was bent or folded. The inventors invented a new display apparatus which can reduce the distortion caused on the folded portion when the display apparatus was bent or folded through various researches and experiments.

An aspect of the present disclosure is to provide an apparatus which can reduce a distortion caused on a folded portion when the display apparatus is bent or folded.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the structure particularly pointed out in the present disclosure, or derivable therefrom, and claims hereof as well as the appended drawings. Additional features, advantages, and aspects of the present disclosure are set forth in part in the

To achieve these and other aspects of the present disclosure, as embodied and broadly described herein, in one or more aspects, a display apparatus may comprise a display panel including a variable area and a non-variable area, a first adhesive member disposed on the display panel and a first layer disposed on the first adhesive member, a material of the first layer being different from a material of the first adhesive member. The first layer may include a photoreactive material.

In another aspect of the present disclosure, a display apparatus may comprise a display panel including a variable area and a non-variable area, a first layer disposed adjacent to the display panel, one or more plates below the display panel and a first adhesive member adjacent to the at least one or more plates. The first layer and the first adhesive member may be configured by (or composed of) different materials.

According to an exemplary embodiment of the present disclosure, an adhesive member applied to the display apparatus is configured by a material which reacts to light so that the defects caused by distortion and/or folded marks (or creases) in the folded portion of the display apparatus may be improved, thereby the performance and/or reliability of the display apparatus may be improved. Thus, an appearance defect is improved to improve the durability of the display apparatus, and the inconvenience of the user caused by the deformation and/or the folded marks (or creases) in the folded portion may be relieved or improved.

According to an exemplary embodiment of the present disclosure, to solve the deformation and/or the folded marks (or creases) in the folded portion, the defects caused by distortion and/or folded marks (or creases) in the folded portion of the display apparatus may be improved, not by an electric signal or heat from the outside, but by a material which reacts to the visible ray when the display apparatus is unfolded.

According to an exemplary embodiment of the present disclosure, a first layer and a first cover member may be configured by a uni-material (in other words, by using the same material). Thus, the first layer is configured as one film together with the first cover member so that components which configure the display apparatus may be unified or simplified.

Other systems, methods, features, and advantages will be, or will become, apparent to one with skill in the art upon reading of the following figures and detailed description. It is intended that all such additional systems, methods, features, and advantages be included within this description, and be within the scope of the present disclosure, and be protected by the following claims. Nothing in this description should be taken as a limitation to the claims. Further aspects and advantages are discussed below in conjunction with aspects of the present disclosure.

It is to be understood that both the foregoing description and the following description of the present disclosure are given by way of example and are intended to provide further explanation of the present disclosure as claimed.

### BRIEF DESCRIPTION OF THE SEVERAL VIEWS OF THE DRAWINGS

The accompanying drawings, which are included to provide a further understanding of the present disclosure, and are incorporated in and constitute a part of the present disclosure, illustrate aspects and embodiments of the present disclosure and together with the description serve to explain principles of the present disclosure.

FIG. 1 illustrates a display apparatus according to an exemplary embodiment of the present disclosure.

FIG. 2 is a cross-sectional view taken along a line I-I′ of FIG. 1 according to an exemplary embodiment of the present disclosure.

FIGS. 3A to 3E are perspective views illustrating a display apparatus according to an exemplary embodiment of the present disclosure.

FIG. 4 illustrates a part of a variable area of a display apparatus according to an exemplary embodiment of the present disclosure.

FIGS. 5A and 5B illustrate a shape of a display apparatus according to an exemplary embodiment of the present disclosure before and after being folded.

FIG. 6 illustrates a display apparatus according to another exemplary embodiment of the present disclosure.

FIG. 7 illustrates a display apparatus according to another exemplary embodiment of the present disclosure.

FIG. 8 illustrates a display apparatus according to another exemplary embodiment of the present disclosure.

FIGS. 9A, 9B, and 9C illustrate a light reaction of a first layer according to another exemplary embodiment of the present disclosure.

Throughout the drawings and the detailed description, unless otherwise described, the same drawing reference numerals should be understood to refer to the same elements, features, or structures. The sizes, lengths, and thicknesses of layers, regions, and elements, and depiction thereof may be enlarged for clarity, illustration, or convenience.

### DETAILED DESCRIPTION

Reference is now made in detail to embodiments of the present disclosure, examples of which may be illustrated in the accompanying drawings. In the following description, where a detailed description of relevant known functions or configurations may unnecessarily obscure aspects of the present disclosure, a detailed description of such known functions or configurations may be omitted for brevity. The progression of processing steps and/or operations described is an example, and the sequence of steps and/or operations are not limited to that set forth herein and may be changed, with the exception of steps and/or operations necessarily occurring in a particular order.

Advantages and features of the present disclosure, and implementation methods thereof are clarified through the embodiments described with reference to the accompanying drawings. The present disclosure may, however, be embodied in different forms and should not be construed as limited to the example embodiments set forth herein. Rather, these exemplary embodiments are provided so that this disclosure may be sufficiently thorough and complete to assist those skilled in the art to understand the inventive concepts fully without limiting the protection scope of the present disclosure.

The shapes, dimensions, areas, ratios, angles, numbers, and the like, which are illustrated in the drawings to describe various exemplary embodiments of the present disclosure, are merely given by way of example. Therefore, the present disclosure is not limited to the illustrations in the drawings. Like reference numerals generally denote like elements throughout the description, unless otherwise specified.

Where a term like “comprise,” “have,” “include,” “contain,” “constitute,” “made up of,” or “formed of,” is used, one or more other elements may be added unless a more limiting term, such as “only” or the like, is used. The terms and names used in the present disclosure are merely used to describe particular embodiments, and are not intended to limit the scope of the present disclosure. An element described in a singular form is intended to include a plurality of elements, and vice versa, unless the context clearly indicates otherwise.

The word “exemplary” is used to mean serving as an example or illustration, unless otherwise specified. Embodiments are exemplary embodiments. Aspects are exemplary aspects. Any implementation described herein as an “example” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, where a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference, unless otherwise specified.

In describing a temporal relationship, when where the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It will be understood that, although the terms “first,” “second,” or the like may be used herein to describe various elements, these elements should not be limited by these terms, for example, to any particular order, precedence, or number of elements. These terms are only used to distinguish one element from another element. For example, a first element could be termed a second element, and, similarly, a second element could be termed a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing the elements of the present disclosure, terms “first,” “second,” “A,” “B,” “(a),” “(b),” or the like may be used. These terms are intended to identify the corresponding element(s) from other element(s), and are not used to define the essence, basis, order, or number of the elements.

Where an element or layer is described as “coupled,” “connected,” “attached,” or “adhered” to another element or layer, the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified.

The term “at least one” should be understood as including any and all combinations of one or more of the associated listed items. For example, the meaning of “at least one of a first item, a second item, and a third item” encompasses the combination of all three listed items, combination of any two of the first item, the second item, and the third item, as well as any individual item, the first item, the second item, or the third item.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In the present disclosure, examples of a display apparatus may include a narrow-sense display apparatus such as a quantum dot module, an organic light emitting diode (OLED) module or a liquid crystal module (LCM) having a display panel and a driver for driving the display panel. Also, examples of the display apparatus may include a set device (or a set apparatus) or a set electronic apparatus such as a notebook computer, a TV, a computer monitor, an equipment apparatus including an automotive apparatus or another type of apparatus for vehicles, or a mobile electronic device like a smartphone or an electronic pad, which is a complete product (or a final product) including an LCM, an OLED module, and a QD module.

Therefore, in the present disclosure, examples of the display apparatus may include a narrow-sense display apparatus itself, such as an LCM, an OLED module, and a QD module, and a set device, which is a final consumer device or an application product including the LCM, the OLED module, and the QD module.

In some embodiments, an LCM, an OLED module, and a QD module including a display panel and a driver may be referred to as a narrow-sense display apparatus, and an electronic apparatus, which is a final product including an LCM, an OLED module, and a QD module may be referred to as a set device. For example, the narrow-sense display device may include a display panel, such an LCM, an OLED module, or a QD module, and a source printed circuit board (PCB), which is a controller for driving the display panel. The set device may further include a set PCB, which is a set controller electrically connected to the source PCB to overall control the set device.

A display panel applied to embodiments of the present disclosure may use any type of display panel, including a liquid crystal display panel, an organic light emitting diode (OLED) display panel, a quantum dot (QD) display panel, and an electroluminescent display panel. The display panel of the embodiment is not limited to a specific display panel capable of bezel bending with a flexible substrate for an organic light emitting diode (OLED) display panel and a lower back plate support structure. Also, a shape or a size of a display panel applied to a display apparatus according to these embodiments is not limited to a shape or a size of a display panel.

In an example where the display panel is an organic light emitting display panel, the display panel may include a plurality of gate lines, data lines, and pixels respectively provided in intersections of the gate lines and the data lines. Also, the display panel may include an array including a thin film transistor (TFT), which is an element for selectively applying a voltage to each of the pixels, a light emitting element layer on the array, and an encapsulation substrate or an encapsulation layer disposed on the array to cover the light emitting element layer. The encapsulation substrate may protect the TFT and the light emitting element layer from an external impact and may prevent water or oxygen from penetrating into the light emitting element layer. Also, a layer provided on the array may include an inorganic light emitting layer, for example, a nano-sized material layer, a quantum dot, or the like.

Features of various embodiments of the present disclosure may be partially or overall coupled to or combined with each other, and may be operated, linked, or driven together in various ways. Embodiments of the present disclosure may be carried out independently from each other, or may be carried out together in co-dependent or related relationship. In one or more aspects, the components of each apparatus according to various embodiments of the present disclosure may be operatively coupled and configured.

Unless otherwise defined, the terms (including technical and scientific terms) used herein have the same meaning as commonly understood by one of ordinary skill in the art to which example embodiments belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, or thickness illustrated in the drawings.

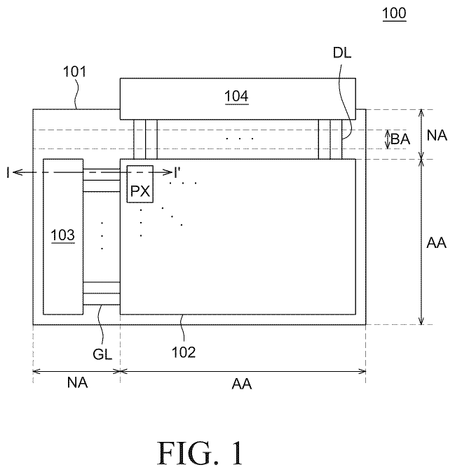

FIG. 1 illustrates a display apparatus according to an exemplary embodiment of the present disclosure.

Referring to FIG. 1, a display apparatus 100 according to an exemplary embodiment of the present disclosure may include a display panel 102. The display panel 102 may include a display area (or an active area) AA provided on a substrate 101 and a non-display area (or a non-active area) NA disposed in a periphery of the display area AA.

The substrate 101 may be formed with a plastic material having a flexibility to be bendable. For example, the substrate 101 may be configured with a material such as polyimide (PI), polyethylene terephthalate (PET), polyethylene naphthalate (PEN), polycarbonate (PC), polyethersulfone (PES), polyarylate (PAR), polysulfone (PSF), and cyclo-olefin copolymer (COC), but the exemplary embodiments of the present disclosure are not limited thereto. For example, as a material of the substrate 101, glass is not excluded. As another exemplary embodiment of the present disclosure, the substrate 101 may be formed of a semiconductor material such as a silicon wafer or the like.

The display area AA is an area where a plurality of sub pixels PX may display images. Each of the plurality of sub pixels PX may be an individual unit which emits light. In each of the plurality of sub pixels PX, a light emitting diode and a driving circuit may be disposed. For example, in the plurality of sub pixels PX, a display element for displaying images and a circuit part for driving the display element may be disposed. For example, when the display apparatus 100 is an organic light emitting display apparatus, the display element may include an organic light emitting display element and when the display apparatus 100 is a liquid crystal display apparatus, the display element may include a liquid crystal element. The plurality of sub pixels PX may include a red sub pixel, a green sub pixel, a blue sub pixel and/or a white sub pixel, but exemplary embodiments of the present disclosure are not limited thereto.

The non-display area NA may be an area where no image is displayed. The non-display area NA may be an area in which various wiring lines and driving ICs for driving a plurality of sub pixels PX disposed in the display area AA are disposed. For example, in the non-display area NA, at least one of a data driver 104 and a gate driver 103 may be disposed, and exemplary embodiments of the present disclosure are not limited thereto.

The non-display area NA may be an area which encloses the display area AA. For example, the non-display area NA may be disposed in vicinity of the periphery of the display area AA. For example, the non-display area NA may be an area extending from the display area AA, or an area in which the plurality of sub pixels PX are not disposed, but exemplary embodiments of the present disclosure are not limited thereto.

The non-display area NA in which the image is not displayed may be a bezel area or further include a bending area BA in which the substrate 101 is bent, but exemplary embodiments of the present disclosure are not limited thereto.

In the display area AA, a plurality of data lines DL and a plurality of gate lines GL may be disposed. For example, the plurality of data lines DL may be disposed in rows or columns, and the plurality of gate lines GL may be disposed in columns or rows. A sub pixel PX may be disposed in an area configured or defined by the data line DL and/or the gate line GL.

The sub pixel PX of the display area AA may include a thin film transistor or a transistor formed of a semiconductor layer. For example, the thin film transistor or the transistor may include an oxide semiconductor material, and exemplary embodiments of the present disclosure are not limited thereto. For example, the thin film transistor may be a transistor, but is not limited by the term.

According to an exemplary embodiment of the present disclosure, in the non-display area NA, a gate driver 103 including a gate driving circuit may be disposed. The gate driving circuit of the gate driver 103 sequentially supplies a scan signal to a plurality of gate lines GL to sequentially drive each pixel row of the display area AA. For example, the pixel row may be a row formed by pixels connected to one gate line GL. The gate driving circuit may be a scan driving circuit or a gate driver, but is not limited by the term.

The gate driving circuit may be configured by a thin film transistor having a polycrystalline semiconductor layer, configured by a thin film transistor having an oxide semiconductor layer, or configured by forming one pair of a thin film transistor having the polycrystalline semiconductor layer and a thin film transistor having an oxide semiconductor layer. When the same semiconductor material is used for the thin film transistors disposed in the non-display area NA and the display area AA, the thin film transistors may be simultaneously configured in the same process, but exemplary embodiments of the present disclosure are not limited thereto.

The gate driving circuit may include a shift register and a level shifter.

In the display apparatus according to an exemplary embodiment of the present disclosure, the gate driving circuit may be implemented in a gate in panel (GIP) type to be directly disposed on the substrate 101.

The gate driver 103 including the gate driving circuit may sequentially supply a scan signal of an on-driving voltage or an off-driving voltage to the plurality of gate lines.

The gate driver 103 according to an exemplary embodiment of the present disclosure may be directly formed on the substrate 101 using the thin film transistor which uses the polycrystalline semiconductor material as the semiconductor layer. Further, the gate driver 103 may be formed by configuring the C-MOS with a thin film transistor using a polycrystalline semiconductor material as a semiconductor layer and a thin film transistor using an oxide semiconductor material as a semiconductor layer.

For example, the oxide semiconductor material may include at least one of an InGaZnO (IGZO) based oxide semiconductor material, an InZnO (IZO) based oxide semiconductor material, an InGaZnSnO (IGZTO) based oxide semiconductor material, an InSnZnO (ITZO) based oxide semiconductor material, a FeInZnO (FIZO) based oxide semiconductor material, a ZnO based oxide semiconductor material, a SiInZnO (SIZO) based oxide semiconductor material, and a Zn-Oxynitride (ZnON) based oxide semiconductor material, but exemplary embodiments of the present disclosure are not limited thereto.

When the thin film transistor having an oxide semiconductor layer and the thin film transistor having a polycrystalline semiconductor layer are included, due to a high electron mobility in a channel theerof, it may be possible to implement high resolution and low power consumption.

The display apparatus 100 according to an exemplary embodiment of the present disclosure may further include a data driver 104 including a data driving circuit. When a specific gate line is open or switched on by the gate driver 103 including the gate driving circuit, image data is converted into a data voltage of an analog type to be supplied to the plurality of data lines.

The plurality of gate lines GL disposed on the substrate 101 may include a plurality of scan lines and a plurality of emission control lines. The plurality of scan lines and the plurality of emission control lines may be lines which transmit different types of gate signals (a scan signal or an emission control signal) to a gate node of different types of transistors (a scan transistor or an emission control transistor).

The gate driver 103 including the gate driving circuit may include a scan driving circuit which outputs scan signals to a plurality of scan lines which is one type of gate lines and an emission driving circuit which outputs emission control signals to a plurality of emission control lines which is another type of gate lines.

The display panel 102 according to an exemplary embodiment of the present disclosure may further include a bending area BA in which the substrate 101 is bent. The bending area BA may be an area where the substrate 101 is bent. The substrate 101 may be maintained in a flat state in an area excluding the bending area BA. The data line DL may be disposed so as to pass through the bending area BA, and various data lines DL are disposed to be connected to the data pad.

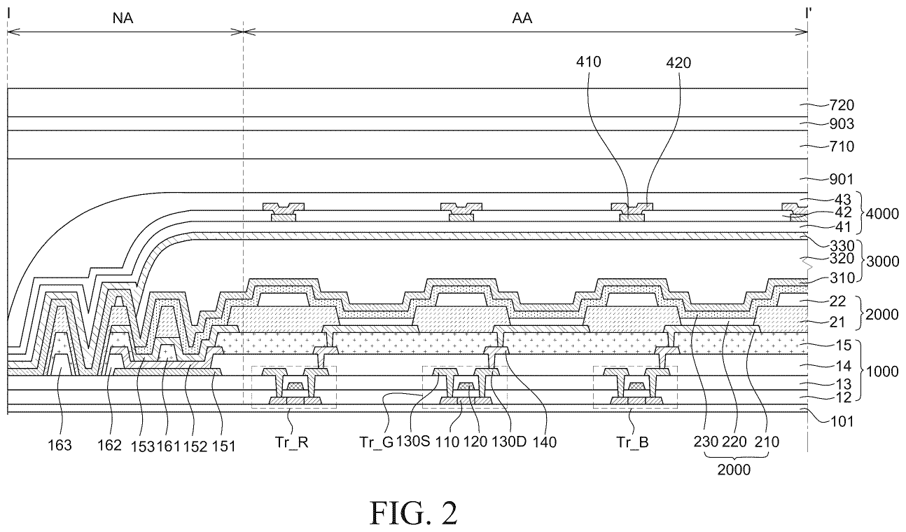

FIG. 2 is a cross-sectional view taken along the line I-I′ of FIG. 1 according to an exemplary embodiment of the present disclosure.

Referring to FIG. 2, the display apparatus according to an exemplary embodiment of the present disclosure may include a display area AA and a non-display area NA. The non-display area NA may be disposed in a periphery of the display area AA.

The substrate 101 may include a first substrate, a second substrate, and an intermediate layer between the first substrate and the second substrate, but exemplary embodiments of the present disclosure are not limited thereto.

For example, the first substrate and the second substrate may be formed of at least one of polyimide, polyethersulfone, polyethylene terephthalate, and polycarbonate, but exemplary embodiments of the present disclosure are not limited thereto. When the substrate 101 is formed of a plastic material, the manufacturing process of the display apparatus is performed under a state in which a support substrate formed of glass is disposed below the substrate 101, and the support substrate may be released after completing the manufacturing process of the display apparatus. Further, after releasing the support substrate, a back plate (or plate) which supports the substrate 101 may be disposed below the substrate 101. When the substrate 101 is formed of a plastic material, moisture may permeate the substrate so that the moisture permeation proceeds to the light emitting diode layer of the transistor part or the emission part so that the performance of the display apparatus may be degraded. The display apparatus according to the exemplary embodiment of the present disclosure may be configured by two substrates including a first substrate and a second substrate configured by a plastic material to suppress the degradation of the performance of the display apparatus due to the moisture permeation. Further, an intermediate layer, for example, which is an inorganic film is formed between the first substrate and the second substrate to block or prevent the permeation of the moisture into the substrate to improve the reliability of the display apparatus. The intermediate layer may be formed of an inorganic film. For example, the intermediate layer may be formed by a single layer of silicon nitride (SiNx) or silicon oxide (SiOx) or a multilayer thereof, but exemplary embodiments of the present disclosure are not limited thereto. For example, the substrate may have a multilayered structure in which a first polyimide film, an inorganic film, and a second polyimide film are sequentially laminated.

A display apparatus (for example, the display panel thereof) disposed on the substrate 101 may include a plurality of areas. In the present disclosure, the plurality of areas include a display area AA and a non-display area NA, but exemplary embodiments of the present disclosure are not limited thereto.

A transistor part 1000, an emission part 2000, an encapsulation part 3000, and a touch part 4000 may be disposed on the substrate 101, but exemplary embodiments of the present disclosure are not limited thereto.

A first buffer layer (or a buffer layer) may be disposed on one side of the display area AA and the non-display area NA on the substrate 101. As the first buffer layer, a buffer layer (or a first buffer layer) which is formed of a single layer of silicon nitride (SiNx) or silicon oxide (SiOx) or a plurality of layers thereof may be disposed. The buffer layer improves the adhesiveness between layers formed on the buffer layer and the substrate 101, and may block or prevent various types of defects such as alkali components leaked from the substrate 101. The buffer layer may delay the diffusion of moisture and/or oxygen which permeates the substrate 101. The buffer layer may also be omitted based on a type or a material of the substrate and a structure and a type of the thin film transistor.

The transistor part 1000 may be disposed on the substrate 101 and/or the buffer layer and in the display area AA and the non-display area NA. The transistors of the display area AA may include a switching transistor or a driving transistor for driving sub pixels. A transistor in the non-display area NA may include a gate driver, for example, a transistor for driving the GIP or a light emitting transistor.

Referring to FIG. 2, in the display area AA, a first driving transistor Tr_R, a second driving transistor Tr_G, and a third driving transistor Tr_B of red R, green G, and blue B sub pixels may be disposed.

Each of the first driving transistor Tr_R, the second driving transistor Tr_G, and the third driving transistor Tr_B may include a semiconductor layer 110, a gate electrode 120, a source electrode 130S, and a drain electrode 130D on the substrate 101 or the buffer layer. The semiconductor layer 110 may be configured by low temperature poly silicon (LTPS) formed of polycrystalline silicon or metal oxide. For example, the metal oxide may be configured by one or more of indium gallium zinc oxide (IGZO), indium zinc oxide (IZO), indium gallium tin oxide (IGTO), and indium gallium oxide (IGO), but exemplary embodiments of the present disclosure are not limited thereto.

The semiconductor layer formed of low temperature poly silicon (LTPS) may form a channel region and a source region or a drain region connected to a source electrode or a drain electrode by electron injection doping.

A conductive property of the metal oxide may be improved by a doping process of injecting impurities, and the metal oxide may include a channel region in which a channel through which electrons and holes move is formed.

A first insulating layer 12 may be disposed on the semiconductor layer 110. The first insulating layer 12 is disposed between the semiconductor layer 110 and the gate electrode 120 to insulate the semiconductor layer 110 and the gate electrode 120 from each other. The first insulating layer 12 may be a gate insulating layer, but exemplary embodiments of the present disclosure are not limited thereto.

The first insulating layer 12 may be formed of an insulating inorganic material such as silicon nitride (SiNx) or silicon oxide (SiOx), but exemplary embodiments of the present disclosure are not limited thereto. For example, the first insulating layer 12 may be formed by an insulating organic material.

The gate electrode 120 may be disposed so as to overlap the semiconductor layer 110. The gate electrode 120 may be formed of a single layer or a plurality of layers formed of any one of silver (Ag), molybdenum (Mo), copper (Cu), titanium (Ti), aluminum (Al), chrome (Cr), nickel (Ni), neodymium (Nd), tungsten (W), and gold (Au), or an alloy thereof, but exemplary embodiments of the present disclosure are not limited thereto.

A second insulating layer 13 may be disposed on the gate electrode 120. The second insulating layer 13 may be an interlayer insulating layer, but exemplary embodiments of the present disclosure are not limited thereto.

The second insulating layer 13 may be formed of an insulating inorganic material such as silicon nitride (SiNx) or silicon oxide (SiOx), but exemplary embodiments of the present disclosure are not limited thereto. For example, the second insulating layer 13 may be formed by an insulating organic material.

The source electrode 130S and the drain electrode 130D may be disposed on the second insulating layer 13. The source electrode 130S and the drain electrode 130D may be connected to the semiconductor layer 110.

The source electrode 130S and the drain electrode 130D may be formed by the same process. The source electrode 130S and the drain electrode 130D may be formed of one or more materials of silver (Ag), molybdenum (Mo), copper (Cu), titanium (Ti), aluminum (Al), chrome (Cr), nickel (Ni), neodymium (Nd), tungsten (W), and gold (Au), but exemplary embodiments of the present disclosure are not limited thereto. As another example, the source electrode 130S and the drain electrode 130D may be formed by at least two layers including a first layer having titanium (Ti) and a second layer having at least one of molybdenum (Mo), copper (Cu), aluminum (Al), silver (Ag), chrome (Cr), gold (Au), neodymium (Nd), and nickel (Ni), but exemplary embodiments of the present disclosure are not limited thereto.

When the source electrode 130S and the drain electrode 130D are formed, a first wiring line 151 may be formed in the non-display area NA using the same process. As another example, the first wiring line 151 may be formed by a process different from that of the source electrode 130S and the drain electrode 130D.

The first wiring line 151 may transmit a low potential voltage EVSS output from a flexible printed circuit board (FPCB) to a cathode electrode 230.

A first passivation layer 14 may be disposed on the source electrode 130S and the drain electrode 130D and a part of the first wiring line 151. The first passivation layer 14 may be a first planarization layer, but exemplary embodiments of the present disclosure are not limited thereto.

The first passivation layer 14 may be formed of an insulating inorganic film such as silicon nitride (SiNx) or silicon oxide (SiOx), or an organic insulating film such as polyacrylate and polyimide, but exemplary embodiments of the present disclosure are not limited thereto.

A connection electrode 140 is disposed on the first passivation layer 14 and the drain electrode 130D and the anode electrode 210 may be electrically connected through a contact hole formed in the first passivation layer 14.

The connection electrode 140 may be formed of one or more materials of silver (Ag), molybdenum (Mo), copper (Cu), titanium (Ti), aluminum (Al), chrome (Cr), nickel (Ni), neodymium (Nd), tungsten (W), and gold (Au), but exemplary embodiments of the present disclosure are not limited thereto. As another example, the connection electrode 140 may be formed by at least two layers including a first layer having titanium (Ti) and a second layer having at least one of molybdenum (Mo), copper (Cu), aluminum (Al), silver (Ag), chrome (Cr), gold (Au), neodymium (Nd), and nickel (Ni), but exemplary embodiments of the present disclosure are not limited thereto.

A second wiring line 152 may be disposed in the non-display area NA by the same process of forming the connection electrode 140. The second wiring line 152 is connected to the first wiring line 151 to be used as an auxiliary electrode which transmits a voltage to the cathode electrode 230.

A second passivation layer 15 may be disposed on the connection electrode 140 and a part of the second wiring line 152. The second passivation layer 15 may be a second planarization layer, but exemplary embodiments of the present disclosure are not limited thereto.

The second passivation layer 15 is formed of an organic insulating film to reduce a step difference caused by wiring lines and contact holes formed below the second passivation layer 15. For example, the organic insulating film may include polyacrylate and polyimide, but exemplary embodiments of the present disclosure are not limited thereto.

The emission part 2000 may be disposed on the transistor part 1000. For example, the emission part 2000 may be disposed on the second passivation layer 15 of the display area AA. The emission part 2000 may include an anode electrode 210, a light emitting diode layer 220, and a cathode electrode 230.

The anode electrode 210 may be electrically connected to the drain electrode 130D of the driving transistor by means of the connection electrode 140. The anode electrode 210 may be formed of at least one or more of silver (Ag), aluminum (Al), gold (Au), molybdenum (Mo), tungsten (W), chrome (Cr), lead (Pd), indium tin oxide (ITO), indium zinc oxide (IZO), or an alloy thereof, but exemplary embodiments of the present disclosure are not limited thereto.

In the non-display area NA, a third wiring line 153 may be disposed by the same process of forming the anode electrode 210. As another example, the third wiring line 153 may be formed by a process different from that of the anode electrode 210.

The third wiring line 153 may be an auxiliary electrode which is connected to the second wiring line 152 and the first wiring line 151 to transmit a voltage to the cathode electrode 230, but exemplary embodiments of the present disclosure are not limited thereto. As another example, at least one or more of the second wiring line 152 and the third wiring line 153 may be omitted.

A bank 21 may be disposed on a part of the anode electrode 210 and the third wiring line 153.

The bank 21 may divide the plurality of sub pixels, minimize a glaring phenomenon, and suppress or prevent color mixture at various viewing angles. The bank 21 exposes a portion of the anode electrode 210 corresponding to the emission area, and may overlap an end portion of the anode electrode 210. The bank 21 may overlap a contact hole formed in the second insulating layer 13 and the first passivation layer 14 and a contact hole formed in the second passivation layer 15.

The bank 21 may be formed of one or more materials among inorganic insulating materials, such as silicon nitride (SiNx) or silicon oxide (SiOx) and organic insulating materials, such as benzocyclobutene (BCB), acrylic resin, epoxy resin, phenolic resin, polyamide resin, or polyimide resin, but exemplary embodiments of the present disclosure are not limited thereto. As another example, the bank 21 may be formed of black material to which black pigment is added to reduce light reflection, but exemplary embodiments of the present disclosure are not limited thereto.

A spacer 22 may be further disposed on the bank 21. The spacer 22 minimizes or reduces the risk of the display apparatus from being broken due to the external impact by buffering an empty space between the substrate 101 on which the light emitting diode layer 220 is formed and an upper substrate. The spacer 22 may be formed of the same material as the bank 21 and the spacer may be formed simultaneously with the bank 21, but exemplary embodiments of the present disclosure are not limited thereto.

The light emitting diode layer 220 may be disposed over an opening of the bank 21 which exposes the anode electrode 210. The light emitting diode layer 220 may include one or more of a red emission layer, a green emission layer, a blue emission layer, and a white emission layer to emit a specific color light, but exemplary embodiments of the present disclosure are not limited thereto.

When the light emitting diode layer 220 includes a white emission layer, the light emitting diode layer 220 may be disposed on the opening of the bank 21 and the entire substrate.

The cathode electrode 230 may be disposed on the light emitting diode layer 220. The cathode electrode 230 may supply electrons to the light emitting diode layer 220. For example, the cathode electrode 230 may be formed of a conductive material having a low work function, but exemplary embodiments of the present disclosure are not limited thereto.

When the display apparatus is a top emission type display apparatus, the cathode electrode 230 may be disposed using a transparent conductive material through which light passes. For example, the cathode electrode 230 may be formed of at least one or more of indium tin oxide (ITO) and indium zinc oxide (IZO), but exemplary embodiments of the present disclosure are not limited thereto.

For example, the cathode electrode 230 may be configured by a translucent conductive material which transmits light. For example, the cathode electrode 230 may be formed of at least one or more of alloys such as LiF/Al, CsF/Al, Mg:Ag, Ca/Ag, Ca:Ag, LiF/Mg:Ag, LiF/Ca/Ag, and LiF/Ca:Ag, but exemplary embodiments of the present disclosure are not limited thereto.

When the display apparatus is a bottom emission type display apparatus, the cathode electrode 230 may be disposed using an opaque conductive material as a reflective electrode which reflects light. For example, the cathode electrode may be configured by at least one or more of silver (Ag), aluminum (Al), gold (Au), molybdenum (Mo), tungsten (W), chrome (Cr), or an alloy thereof, but exemplary embodiments of the present disclosure are not limited thereto.

The light emitting diode layer 220 may further include a hole injection layer, a hole transport layer, an electron transport layer, and an electron injection layer, in addition to the emission layer, but exemplary embodiments of the present disclosure are not limited thereto.

For example, the light emitting diode layer 220 may be formed by laminating a hole transfer layer, the emission layer, and an electron transfer layer on the anode electrode 210 in this order or a reverse order. For example, the hole transfer layer may be a layer which injects holes into the emission layer or transmits the holes. For example, the hole transfer layer may be a hole injection layer, a hole transport layer, and an electron blocking layer, but exemplary embodiments of the present disclosure are not limited thereto. The electron convey layer may be a layer which injects the electrons to the emission layer or transmits the electrons. For example, the electron transfer layer may be an electron injection layer, an electron transport layer, and a hole blocking layer, but exemplary embodiments of the present disclosure are not limited thereto.

The light emitting diode layer 220 may include one emission part. The one emission part may include a red emission layer, a green emission layer, and a blue emission layer which emit red light, green light, and blue light respectively for every sub pixel PXL.

The light emitting diode layer 220 may include two or more emission parts. The emission part may be referred to a stack, but is not limited by the term. The two or more emission parts may include a first emission part and a second emission part. The first emission part and the second emission part may include a red emission layer, a green emission layer, and a blue emission layer which emit red light, green light, and blue light respectively for every sub pixel PXL. The two or more emission layers included in the first emission part and the second emission part may be emission layers which emit a same color light (in other words, light of the same color). As another example, the first emission layer included in the first emission part may be a blue emission layer, a sky blue emission layer, a dark blue emission layer, a blue emission layer, and a red emission layer, a sky blue emission layer and a red emission layer, and a dark blue emission layer and a red emission layer. However, exemplary embodiments of the present disclosure are not limited thereto. For example, the second emission layer included in the second emission part may be a yellow emission layer, a yellow-green emission layer, a green emission layer, a yellow emission layer and a red emission layer, a yellow-green emission layer and a red emission layer, a green emission layer and a red emission layer, a combination of a yellow emission layer, a yellow-green emission layer, and a green emission layer, a combination of a yellow emission layer, a yellow-green emission layer, a green emission layer, and a red emission layer, a combination of two yellow-green emission layers and one green emission layer, a combination of one yellow-green emission layer and two green emission layers, a combination of two yellow-green emission layers, one green emission layer, and a red emission layer, and a combination of one yellow-green emission layer, two green emission layers, and a red emission layer. However, exemplary embodiments of the present disclosure are not limited thereto. A charge generation layer may be configured between the first emission part and the second emission part. The charge generation layer may include an n-type charge generation layer and a p-type charge generation layer. Each of the first emission part and the second emission part may include one or more of a hole injection layer, a hole transport layer, a hole blocking layer, an electron blocking layer, an electron transport layer, and an electron injection layer, but exemplary embodiments of the present disclosure are not limited thereto.

The two or more emission parts may include a first emission part, a second emission part, and a third emission part. The first emission layer included in the first emission part may be the same as that described above. The second emission layer included in the second emission part may be the same as that described above. The third emission layer included in the third emission part may be configured to be the same as the first emission layer, but exemplary embodiments of the present disclosure are not limited thereto. A first charge generation layer may be configured between the first emission part and the second emission part. The first charge generation layer may include an n-type charge generation layer and a p-type charge generation layer. A second charge generation layer may be configured between the second emission part and the third emission part. The second charge generation layer may include an n-type charge generation layer and a p-type charge generation layer. Each of the first emission part, the second emission part, and the third emission part may include one or more of a hole injection layer, a hole transport layer, a hole blocking layer, an electron blocking layer, an electron transport layer, and an electron injection layer, but exemplary embodiments of the present disclosure are not limited thereto.

The two or more emission parts may include a first emission part, a second emission part, a third emission part, and a fourth emission part. At least two or more emission layers among the first emission part, the second emission part, the third emission part, and the fourth emission part may be configured by emission layers which emit a same color light (in other words, light of the same color). For example, at least two emission layers among the first emission part, the second emission part, the third emission part, and the fourth emission part may be configured by blue emission layers, but exemplary embodiments of the present disclosure are not limited thereto. At least one emission layer among the first emission part, the second emission part, the third emission part, and the fourth emission part may include an emission layer other than the blue emission layer. For example, at least one or more emission layers among the first emission part, the second emission part, the third emission part, and the fourth emission part may include a yellow emission layer, a yellow-green emission layer, a green emission layer, a yellow emission layer and a red emission layer, a yellow-green emission layer and a red emission layer, a green emission layer and a red emission layer, a combination of a yellow emission layer, a yellow-green emission layer, and a green emission layer, a combination of a yellow emission layer, a yellow-green emission layer, a green emission layer, and a red emission layer, a combination of two yellow-green emission layers and one green emission layer, a combination of one yellow-green emission layer and two green emission layers, a combination of two yellow-green emission layers, one green emission layer, and a red emission layer, and a combination of one yellow-green emission layer, two green emission layers, and a red emission layer. However, exemplary embodiments of the present disclosure are not limited thereto. A first charge generation layer may be configured between the first emission part and the second emission part. The first charge generation layer may include an n-type charge generation layer and a p-type charge generation layer. A second charge generation layer may be configured between the second emission part and the third emission part. The second charge generation layer may include an n-type charge generation layer and a p-type charge generation layer. A third charge generation layer may be configured between the third emission part and the fourth emission part. The third charge generation layer may include an n-type charge generation layer and a p-type charge generation layer. Each of the first emission part, the second emission part, the third emission part, and the fourth emission part may include one or more of a hole injection layer, a hole transport layer, a hole blocking layer, an electron blocking layer, an electron transport layer, and an electron injection layer, but exemplary embodiments of the present disclosure are not limited thereto.

In the non-display area NA of the display apparatus, an end portion including a dam part in which a driving circuit part and a plurality of dams are disposed may be disposed. The end portion of the non-display area NA may be an area in which the display apparatus is enclosed by a connection part in which the cathode electrode 230 and the EVSS line are electrically connected, the encapsulation layer, and the plurality of dams. In the end portion, the first insulating layer 12, the second insulating layer 13, the first passivation layer 14, and the second passivation layer 15 which are disposed on the substrate 101 may extend.

The wiring lines may be disposed at the end portion to connect the power voltage and the touch signals applied from the flexible printed circuit board (FPCB) of the display apparatus through the wiring lines.

The plurality of dams may be disposed at the end portion of the non-display area NA. Among the plurality of dams, one or more insulating layers may be laminated to suppress or prevent the second encapsulation layer 320 formed of an organic layer, from being leaked to the outside, but exemplary embodiments of the present disclosure are not limited thereto.

The plurality of dams may include a first dam 161, a second dam 162, and a third dam 163, and may include at least two or more dams, but is not limited to the number of dams. Each of the first dam 161, the second dam 162, and the third dam 163 may enclose or surround the display area AA.

Each of the first dam 161, the second dam 162, and the third dam 163 may have a first height, a second height, and a third height. For example, the second height may be higher than the first height and the third height may be lower than the second height.

Even though the second encapsulation layer 320 overflows the first dam 161, the leakage of the second encapsulation layer 320 to the outside may be suppressed or prevented by the second dam 162.

The first dam 161, the second dam 162, and the third dam 163 may be formed of the first passivation layer 14, the second passivation layer 15, the bank 21, and the spacer 22.

The first wiring line 151 may be disposed below the second passivation layer 15 which configures the first dam 161 and the first passivation layer 14 which configures the second dam 162. The second wiring line 152 may be disposed below the second passivation layer 15 which configures the first dam 161 and the second dam 162. The third wiring line 153 may be disposed below the bank 21 of the first dam 161.

The first wiring line 151, the second wiring line 152, and the third wiring line 153 are in contact with each other in the area of the first dam 161 and the second dam 162 to be electrically connected to transmit a voltage to the cathode electrode 230.

The first wiring line 151, the second wiring line 152, and the third wiring line 153 may be disposed so as to overlap a part of the gate driver of the driving circuit. For example, the gate driver may be a gate-in-panel (GIP), but exemplary embodiments of the present disclosure are not limited thereto.

A capping layer may be disposed on the cathode electrode 230. The capping layer protects the cathode electrode 230 and may improve external luminous efficiency. For example, the capping layer may be configured by organic or inorganic film. For example, the capping layer may be configured of the metal material such as lithium fluoride (LiF) as inorganic films or further includes an organic film, but exemplary embodiments of the present disclosure are not limited thereto.

The encapsulation part 3000 may be disposed on the emission part 2000. For example, the encapsulation part 3000 may be disposed on the cathode electrode 230 and the capping layer. The encapsulation part 3000 may protect the display apparatus from moisture, oxygen, or foreign materials from the outside. For example, the encapsulation part 3000 suppresses the permeation of oxygen and moisture from the outside to suppress or prevent oxidation of the emission material and the electrode material.

The encapsulation part 3000 may be formed of a transparent material to transmit light emitted from the light emitting diode layer 220.

The encapsulation part 3000 may include a first encapsulation layer 310, a second encapsulation layer 320, and a third encapsulation layer 330, but exemplary embodiments of the present disclosure are not limited thereto. The first encapsulation layer 310, the second encapsulation layer 320, and the third encapsulation layer 330 may have a sequentially laminated structure, but exemplary embodiments of the present disclosure are not limited thereto.

The first encapsulation layer 310 and the third encapsulation layer 330 may be formed of one or more materials of silicon nitride (SiNx), silicon oxide (SiOx), and aluminum oxide (AlyOz), but exemplary embodiments of the present disclosure are not limited thereto.

The second encapsulation layer 320 may cover foreign materials or particles which may be generated during a manufacturing process of the display apparatus. The second encapsulation layer 320 may planarize a surface of the first encapsulation layer 310.

The second encapsulation layer 320 may include an organic material, for example, silicon oxy carbon (SiOCz), epoxy, polyimide, polyethylene, or a polymer such as acrylate, but exemplary embodiments of the present disclosure are not limited thereto.

A touch part 4000 for touch operation of the display apparatus may be disposed on the third encapsulation layer 330. For example, the touch part 4000 may include a buffer layer 41, a bridge electrode 410, a touch electrode 420, a third insulating layer 42, and a third passivation layer 43, but exemplary embodiments of the present disclosure are not limited thereto. According to another exemplary embodiment of the present disclosure, the touch part 4000 may be disposed on a polarization member 710.

For example, in the touch part 4000, a buffer layer 41 (or a second buffer layer) may be disposed on the third encapsulation layer 330. The buffer layer 41 may enhance an adhesiveness between layers formed on the buffer layer 41 and the third encapsulation layer 330. The buffer layer 41 may extend to an area in which the flexible PCB (FPCB) disposed in the non-display area NA and a connection part of the substrate 101 are disposed. The buffer layer 41 may be formed by a single layer of silicon nitride (SiNx) or silicon oxide (SiOx) or a multilayer thereof, but exemplary embodiments of the present disclosure are not limited thereto.

The bridge electrode 410 may be disposed on the buffer layer 41. The bridge electrode 410 electrically connects the touch electrodes 420 and may transmit a touch signal. The bridge electrode 410 may be formed of a single layer or a plurality of layers formed of any one of silver (Ag), molybdenum (Mo), copper (Cu), titanium (Ti), aluminum (Al), chrome (Cr), nickel (Ni), neodymium (Nd), tungsten (W), and gold (Au), or an alloy thereof, but exemplary embodiments of the present disclosure are not limited thereto.

A third insulating layer 42 may be disposed on the bridge electrode 410. The third insulating layer 42 may connect spaced touch electrodes 420 to the bridge electrode 410 through a contact hole formed in the third insulating layer 42. For example, the third insulating layer 42 may be an insulating layer disposed in the touch part 4000 so that the third insulating layer may be a touch insulating layer, but exemplary embodiments of the present disclosure are not limited thereto. For example, the third insulating layer 42 may be formed by a single layer of silicon nitride (SiNx) or silicon oxide (SiOx) or a multilayer thereof, but exemplary embodiments of the present disclosure are not limited thereto.

A touch electrode 420 may be disposed on the third insulating layer 42. The touch electrode 420 may be connected to a plurality of touch lines disposed in the non-display area NA to be connected to a touch circuit in the flexible PCB (FPCB).

The touch circuit supplies a touch driving signal to the touch electrode 420, detects a touch sensing signal from the touch electrode 420, and may sense the presence of touch and/or a touch position (coordinate) based thereon to perform a touch operation.

The touch electrode 420 may be formed of a single layer or a plurality of layers formed of any one of silver (Ag), molybdenum (Mo), copper (Cu), titanium (Ti), aluminum (Al), chrome (Cr), nickel (Ni), neodymium (Nd), tungsten (W), and gold (Au), or an alloy thereof, but exemplary embodiments of the present disclosure are not limited thereto. For example, the touch electrode 420 and the bridge electrode 410 may be disposed in a position corresponding to the bank 21 and the spacer 22.

The third passivation layer 43 may be disposed on the touch electrode 420. The third passivation layer 43 may extend to an area in which the flexible PCB (FPCB) in the non-display area NA and a connection part of the substrate 101 are disposed.

The third passivation layer 43 may be formed of one or more materials among inorganic insulating materials, such as silicon nitride (SiNx) or silicon oxide (SiOx) or organic insulating materials, such as benzocyclobutene (BCB), acrylic resin, epoxy resin, phenolic resin, polyamide-based resin, or polyimide-based resin, but exemplary embodiments of the present disclosure are not limited thereto.

The polarization member 710 may be disposed on the third passivation layer 43. For example, the polarization member 710 may be an optical control layer, but is not limited by the term. The polarization member 710 may suppress or prevent light entering from the outside of the display panel from being in contact with the cathode electrode 230 between the sub pixels to be reflected, so that the visibility of the display apparatus may be improved.

A lower adhesive layer (or a first adhesive member 901) may be disposed between the third passivation layer 43 and the polarization member 710. A cover member, for example, a first cover member 720 may be disposed on the polarization member 710. For example, the first cover member 720 may be a cover window or a window cover, but is not limited by the term. An upper adhesive member (or a second adhesive member) 903 may be disposed between the polarization member 710 and the first cover member 720. For example, the lower adhesive layer (or the first adhesive member) 901 may be the second adhesive member, the upper adhesive layer (or the second adhesive member) 903 may be the first adhesive member, and the first adhesive member and the second adhesive member may be exchangeably used.

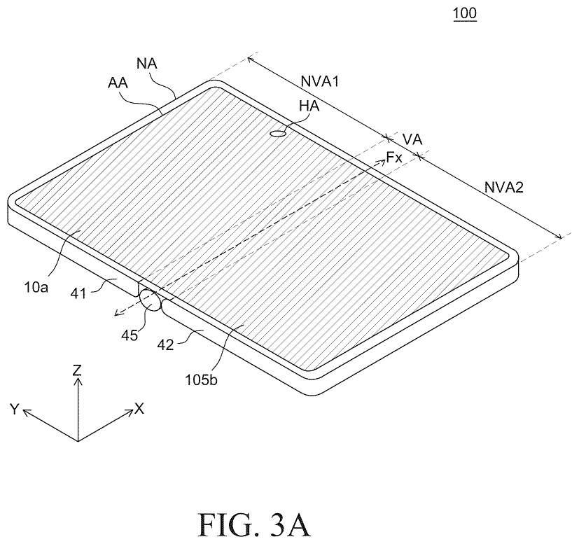

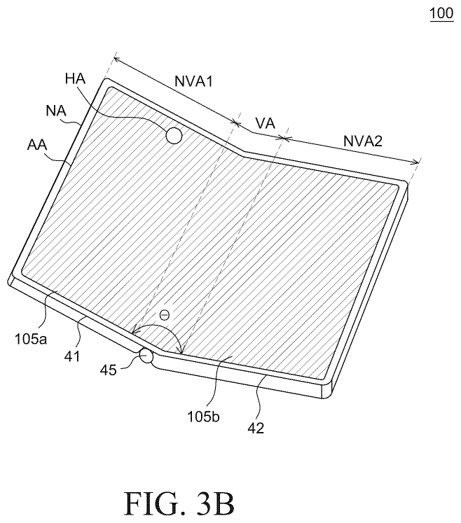

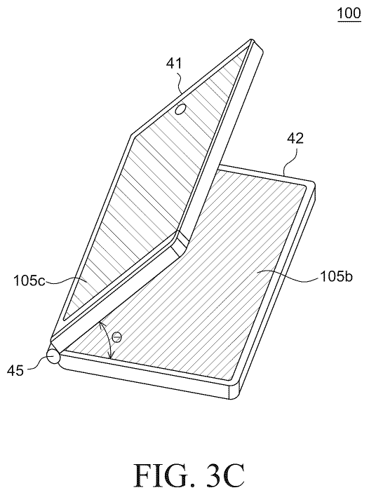

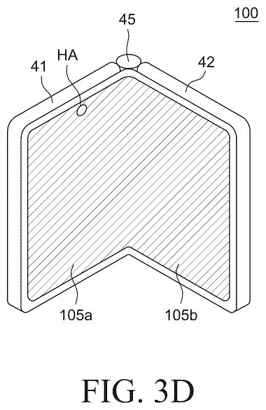

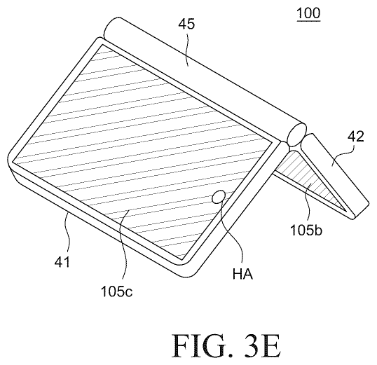

FIGS. 3A to 3E are perspective views of a display apparatus according to an exemplary embodiment of the present disclosure.

Referring to FIGS. 3A to 3E, the display apparatus 100 according to an exemplary embodiment of the present disclosure may include a display area AA, a non-display area NA, and a hole area HA.

The display area AA may be an area where images are displayed. The non-display area NA is disposed at an edge of the display area AA and images may not be displayed in the non-display area NA.

The display apparatus 100 may include a variable area VA and a non-variable areas (for example, a first non-variable area NVA1 and a second non-variable area NVA2) depending on whether it is variable. For example, the variable may include (or involve) foldable, bendable, flexible or the like, but exemplary embodiments of the present disclosure are not limited thereto. For example, the variable may include all from a fully foldable structure to structures which are bendable in a level of a few nanometers. For example, the display apparatus 100 may include a variable area VA and a non-variable areas NVA1 and NVA2 depending on whether it is folded or bent. The display apparatus 100 may include a foldable display apparatus, a bendable display apparatus, a curved display apparatus, a variable display apparatus, or a flexible display apparatus, but exemplary embodiments of the present disclosure are not limited thereto. Here, a case that the display apparatus 100 is a foldable apparatus will be described as an example, but exemplary embodiments of the present disclosure are not limited thereto.

The variable area VA may be an area which is folded when the display apparatus 100 is folded. For example, the variable area VA may be a folding area. For example, the variable area VA may be folded along a specific radius of curvature with respect to a folding axis Fx. For example, the folding axis Fx of the variable area VA may be formed in an X-axis direction, and the non-variable areas (for example, the first non-variable area NVA1 and the second non-variable area NVA2) may extend from the variable area VA in a Y-axis direction perpendicular to the folding axis Fx. When the variable area VA is folded with respect to the folding axis Fx, the variable area VA may form a part of a circle or an ellipse. A radius of curvature of the variable area VA may be a radius of a circle or an ellipse formed by the variable area VA, but exemplary embodiments of the present disclosure are not limited thereto.

The non-variable areas (for example, the first non-variable area NVA1 and the second non-variable area NVA2 may be an area which is not folded when the display apparatus 100 is folded. For example, the non-variable areas (for example, the first non-variable area NVA1 and the second non-variable area NVA2) may maintain a flat state when the display apparatus 100 is folded. The non-variable area (for example, the first non-variable area NVA1 and the second non-variable area NVA2) may be disposed on both sides of the variable area VA, but exemplary embodiments of the present disclosure are not limited thereto. For example, the non-variable area (for example, the first non-variable area NVA1 and the second non-variable area NVA2) may be areas which extend in a Y-axis direction with respect to a folding axis Fx. In this case, the variable area VA may be disposed between the non-variable areas (for example, the first non-variable area NVA1 and the second non-variable area NVA2). For example, when the display apparatus 100 is folded with respect to the folding axis Fx, the non-variable areas (for example, the first non-variable area NVA1 and the second non-variable area NVA2) may overlap each other. For example, the non-variable areas (for example, the first non-variable area NVA1 and the second non-variable area NVA2) may overlap a part of the display area AA and a part of the non-display area NA.

For example, when it is assumed that a top surface (or an upper surface) of the display apparatus 100 on which the image is displayed is a display surface, and a bottom surface (or a lower surface) of the display apparatus 100 which is an opposite surface of the display surface is a rear surface, the variable area VA may be folded by one of an outer folding manner and an inner folding manner. According to the outer folding manner, the variable area VA is folded to expose the display surface of the display apparatus 100 to the outside, and according to the inner folding manner, the variable area VA is folded such that the display surfaces of the display apparatus 100 face each other. However, exemplary embodiments of the present disclosure are not limited thereto.

For example, the variable area VA may be an area which is bent with a predetermined curvature when the display apparatus 100 is folded by at least one of the inner folding and the outer folding. An area other than the non-variable areas for example, the first non-variable area NVA1 and the second non-variable area NVA2) may be a variable area VA.

The display apparatus 100 may further include a hinge structure for folding the display panel and a housing (or casing) which supports and accommodates the display panel. The variable area VA and the non-variable areas NVA1 and NVA2 may be applied to the components of the display apparatus in the same way.

Referring to FIGS. 3A to 3E, the display apparatus 100 may include a first housing 41 and a second housing 42. The first housing 41 and the second housing 42 are coupled or connected by a connection member 45 to be rotatable. For example, the connection member 45 may be formed on a side surface of the first housing 41. The connection member 45 of the first housing 41 may include a hinge. The connection member 45 may be formed on a side surface of the second housing 42. The connection member 45 of the second housing 42 may include a hinge, but exemplary embodiments of the present disclosure are not limited thereto. The connection member (for example, hinge) 45 formed on the side surface of the first housing 41 is coupled or connected to the connection member 45 formed on the side surface of the second housing 42 to be rotatably connected. According to another exemplary embodiment of the present disclosure, the connection member 45 may be integrally formed with the first housing 41 or the second housing 42.

Referring to FIGS. 3B and 3D, a folding manner such that a first display surface 105a and a second display surface 105b of the display apparatus 100 face to each other is illustrated. For example, an unfolded state in which a bottom surface (or a lower surface) of the first housing 41 and a top surface (or an upper surface) of the second housing 42 are disposed on one plane with respect to the connection member 45 to be unfolded is provided.

Referring to FIGS. 3C and 3E, the first housing 41 and the second housing 42 may be folded to face each other with respect to the connection member, and a state in which the first housing 41 and the second housing 42 are unfolded at a predetermined angle is shown. An angle θ formed by the first housing 41 and the second housing 42 may be a right angle or an obtuse angle, but exemplary embodiments of the present disclosure are not limited thereto.

In the folded state of the display apparatus 100, a third display surface 105c corresponding to the display area AA may be exposed to the outside. Here, the third display surface 105c may be a display surface in a state in which the display apparatus 100 is folded. For example, in the folded state of the display apparatus 100, the display apparatus 100 may activate the display area AA corresponding to the third display surface 105c. When the display apparatus 100 is unfolded, the second display surface 105b may be inactivated. Here, the second display surface 105b may be a display surface when the display apparatus 100 is unfolded. The activation is to display a screen corresponding to the display area AA. The activation may be to display a screen in a part of the display area AA. Alternatively, the activation is to supply a power to a sub pixel or a pixel corresponding to the display area AA to display a screen. Alternatively, the activation is to change the display apparatus 100 from a sleep state to an active state. The display area AA corresponding to an edge (or a periphery) of the first housing 41 and an edge (or a periphery) of the second housing 42 may be inactivated. The inactivation may be turning off a screen corresponding to the display area AA. Alternatively, the inactivation may not supply power to a sub pixel or a pixel corresponding to the display area AA to display a screen. Alternatively, the inactivation may be to change the display apparatus 100 from the active state to the sleep state.

According to another exemplary embodiment of the present disclosure, in the folded state of the display apparatus 100, the third display surface 105c corresponding to the display area AA may be exposed to the outside. For example, in the folded state of the display apparatus 100, the display apparatus 100 may activate the display area AA corresponding to the third display surface 105c. When the display apparatus 100 is unfolded, the second display surface 105b may be activated. The display surface 105b and the second display surface 105c are associated to each other to display as one and the same display surface, but exemplary embodiments of the present disclosure are not limited thereto.

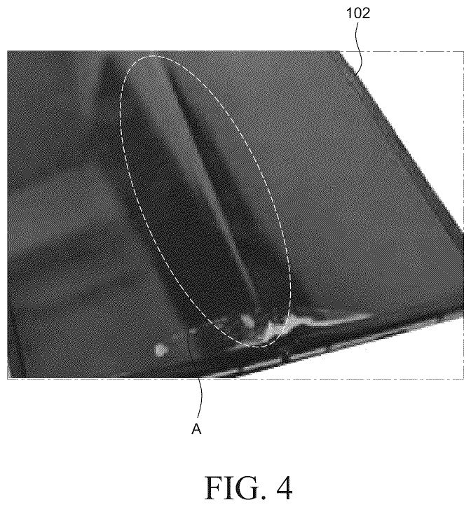

FIG. 4 illustrates a part of a variable area of a display apparatus according to an exemplary embodiment of the present disclosure.

FIG. 4 illustrates a folded portion A of the variable area VA of FIGS. 3A to 3E. For example, the foldable display apparatus including a variable area VA needs to be folded and unfolded so that materials configured above the display panel 102 may be configured by (or composed of) flexible polymers. When the flexible polymers (or polymer material) are bent or folded, the folded portion A may be deformed. when the folded portion A is deformed, it may not return to the flat state which is the original state and marks or creases remain on the surface of the display panel 102. However, the marks or creases are recognized by a user who uses the display apparatus so that the inconvenience is caused to the user or degradation of the visibility and the touching sense occurs.

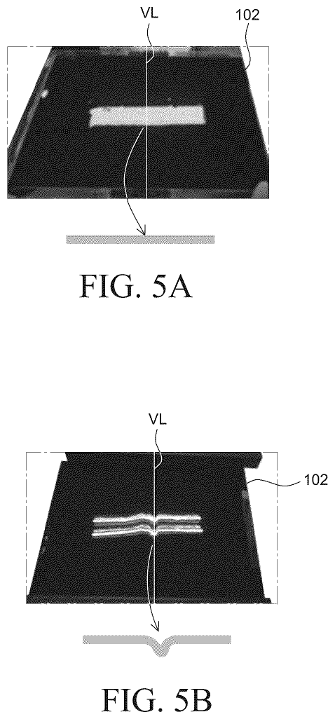

FIGS. 5A and 5B illustrate a shape of a display apparatus according to an exemplary embodiment of the present disclosure before and after being folded.

FIG. 5A illustrates a shape before folding the display apparatus and FIG. 5B illustrates a shape after folding the display apparatus.

Referring to FIG. 5B, a mark is generated in the folded portion A of the display panel 120 of FIG. 4 and deformation occurs along a variable line VL, and the mark or crease is generated by the deformation.

Accordingly, the inventors of the present disclosure conducted various researches and experiments to reduce the distortion caused on the folded portion when the foldable display apparatus is bent or folded. The inventors invented a new display apparatus which reduced the distortion caused on the folded portion when the foldable display apparatus was bent or folded through various researches and experiments.

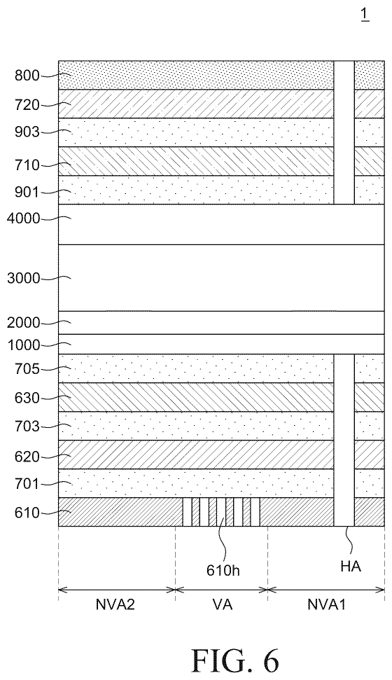

FIG. 6 illustrates a display apparatus according to an exemplary embodiment of the present disclosure.

Referring to FIGS. 2 and 6, a display apparatus 1 or a display panel according to the exemplary embodiment of the present disclosure may include a transistor part 1000, an emission part 2000, an encapsulation part 3000, and a touch part 4000.

The transistor part 1000 may be disposed on the substrate 101. The emission part 2000 may be disposed on the transistor part 1000. The encapsulation part 3000 may be disposed on the emission part 2000. The touch unit 4000 may be disposed on the encapsulation part 3000. The transistor part 1000, the emission part 2000, the encapsulation part 3000, and the touch part 4000 are substantially the same as those described in FIG. 2 so that a description thereof may be omitted or will be briefly given. The display panel may include the transistor part 1000, the emission part 2000, the encapsulation part 3000, and the touch part 4000, but exemplary embodiments of the present disclosure are not limited thereto.

When the display apparatus 1 is folded or bent, the display panel having a flexibility may have a difficulty to maintain a shape of the display panel to a predetermined shape and may be vulnerable to external stimulation. Accordingly, various types of supporting members may be disposed on a rear surface of the display panel or the transistor part 1000. For example, one or more plates may be disposed below the display panel or the transistor part 1000. For example, one or more plates may be included below the display panel or the transistor part 1000. For example, as the one or more plates, a first plate 610, a second plate 620, and a third plate 630 may be disposed, but exemplary embodiments of the present disclosure are not limited thereto. For example, the transistor part 1000 may be disposed on one or more plates.

For example, when a substrate formed of plastic material 101 is applied, the thickness of the substrate 101 is thin so that a sagging of the display panel may be generated at the time of folding or bending. To compensate for the sagging of the display panel, a third plate 630 may be disposed on the rear surface of the display panel or the transistor part 1000. For example, the third plate 630 may be configured by polyimide, but exemplary embodiments of the present disclosure are not limited thereto. For example, the third plate 630 may be a back plate or a support plate, but is not limited by the term.

The first plate 610 may reinforce the rigidity of the substrate 101 formed of plastic material and the second plate 620. The first plate 610 may be configured by a metal having an excellent thermal conductivity. For example, the first plate may be formed of a metal material, such as stainless steel (SUS), carbon fiber reinforced plastics (CFRP), invar (alloys of Fe and Ni), aluminum (Al), and magnesium (Mg), but exemplary embodiments of the present disclosure are not limited thereto. For example, the metal material has a rigidity higher than the plastic material to further improve the durability of the display apparatus 1.

The first plate 610 may include one or more opening patterns (or openings) 610h. For example, the one or more opening patterns 610h may be disposed so as to correspond to the variable area VA of the display apparatus 1. The one or more opening patterns 610h allow the first plate 610 of the variable area VA to be easily folded and effectively relieve the stress applied to the first plate 610 during the folding. Further, to easily recover after the folding, the folding characteristic of the display apparatus 1 may be improved.

The one or more opening patterns 610h extend in a direction parallel to the folding axis (see Fx of FIG. 3A) and may be configured in a discontinuous shape. A length of the respective one or more opening patterns 610h may be shorter than a width in the folding axis Fx of the first plate 610. The shape and the placement method of the one or more opening patterns 610h are not limited to those illustrated. Intervals of two or more opening patterns 610h which are adjacent to each other in a direction perpendicular to the folding axis Fx may be constant, but exemplary embodiments of the present disclosure are not limited thereto. For example, the one or more opening patterns 610h may be configured in a predetermined shape, but exemplary embodiments of the present disclosure are not limited thereto. For example, in the case that the one or more opening patterns 610h are two or more opening patterns 610h, the two or more opening patterns 610h may be configured in different shapes or with different intervals in the variable area VA, but exemplary embodiments of the present disclosure are not limited thereto. For example, the interval of each of two or more opening patterns 610h which are adjacent to each other in a direction perpendicular to the folding axis Fx may be increased as it is far from the folding axis Fx. The two or more opening patterns 610h which are adjacent to each other in a direction perpendicular to the folding axis Fx may have a first interval at a center portion adjacent to the folding axis Fx and may have a second interval which is larger than the first interval in both edge portions of the center portion. For example, the one or more opening patterns 610h may have an elongated circle, a rectangle, a rhombus, and a circle, but exemplary embodiments of the present disclosure are not limited thereto.

The second plate 620 may be disposed on the first plate 610. For example, the second plate 620 may enhance the rigidity of the display panel and/or the transistor part 1000. For example, the second plate 620 may be formed of a metal material, such as stainless steel (SUS), carbon fiber reinforced plastics (CFRP), invar, aluminum (Al), and magnesium (Mg), but exemplary embodiments of the present disclosure are not limited thereto. As another example, the second plate 620 may be configured with a material different from that of the first plate 610. For example, the second plate 620 may be configured by polymer which blocks ultraviolet ray. For example, the second plate 620 may be formed of polyethylene terephthalate (PET) having a black color, but exemplary embodiments of the present disclosure are not limited thereto. The first plate 610 is a bottom plate and the second plate 620 may be a top plate, but is not limited by the term.

At least one or more adhesive members may be disposed in the display area AA. For example, the at least one or more adhesive members may be disposed between two or more plates. For example, the at least one or more adhesive members may include a first adhesive member 701, a second adhesive member 703, and a third adhesive member 705, but exemplary embodiments of the present disclosure are not limited thereto. The first adhesive member 701 may be disposed between the first plate 610 and the second plate 620. The second adhesive member 703 may be disposed between the second plate 620 and the third plate 630. The third adhesive member 705 may be disposed between the third plate 630 and the transistor part 1000. For example, the first adhesive member 701 may cover the one or more opening patterns 610h of the first plate 610. For example, the first adhesive member 701 to the third adhesive member 705 may be at least one or more third adhesive members, but are not limited by the term. For example, the first adhesive member and the third adhesive member may be exchangeably used.

The first adhesive member 701, the second adhesive member 703, and the third adhesive member 705 may be configured by one of optically cleared adhesive member (OCA), optically cleared resin (OCR), and a pressure sensitive adhesive (PSA).

The polarization member 710 may be disposed on the encapsulation part 4000. One or more cover members may be disposed on the polarization member 710. The one or more cover members may include a first cover member 720, but exemplary embodiments of the present disclosure are not limited thereto. For example, the cover member may be a front member, a cover window, or a window cover, but exemplary embodiments of the present disclosure are not limited thereto.

The display apparatus 1 according to an exemplary embodiment of the present disclosure may include a hole area HA. The hole area HA may be disposed in a periphery of the display area AA.

For example, the hole area HA may be disposed in a part of the one or more plates and a part of the one or more cover members. For example, the hole area HA may be disposed in a part of at least one plate of the first plate 610, the second plate 620, and the third plate 630, and a part of the first cover member 720. For example, the hole area HA in at least one or more plates of the first plate 610, the second plate 620, and the third plate 630 is an empty space. The display apparatus 1 of FIG. 6 in which the hole area HA is disposed may be referred to as a under display panel (UDC), but is not limited by the term. For example, the display area of the hole area is formed of a sparse structure and may be a structure to receive light from the outside by a camera in the hole area HA. For example, in the hole area HA, at least one or more of a camera, a sensor, and an optical component may be disposed, but exemplary embodiments of the present disclosure are not limited thereto. For example, the sensor may be an infrared sensor, but exemplary embodiments of the present disclosure are not limited thereto.

According to an exemplary embodiment of the present disclosure, the one or more cover members may be disposed on the encapsulation part 4000. For example, the first cover member 720 may be disposed on the encapsulation part 4000. For example, the first cover member 720 may protect the display apparatus 1 so as not to be damaged due to the external impact or protect the display apparatus 1 including the emission part 2000 so as not to be degraded due to moisture, oxygen, or foreign materials entering from the outside.

Therefore, the first cover member 720 may be configured of a material which is transparent and has excellent impact resistance and scratch resistance. For example, the first cover member 720 may protect the display panel while being easily bent according to the external force without causing the crack. For example, the first cover member 720 may be configured by a film, formed of materials such as polyimide, clear polyimide or colorless polyimide (CPI), polyamide, polyethylene terephthalate, polymethylmethacrylate, polypropylene glycol, and polycarbonate, but exemplary embodiments of the present disclosure are not limited thereto. As another example, the first cover member 720 may be configured by a film formed of photoisotropic polymers such as cycloolefin (co)polymers, photoisotropic polycarbonates, and photoisotropic polymethyl methacrylates, but exemplary embodiments of the present disclosure are not limited thereto. As another example, the first cover member 720 may be configured by chemically strengthened thin glass. A protection film may be disposed on the first cover member 720 to suppress or prevent the scattering. For example, the first cover member 720 may be a thin cover glass (TCG), but exemplary embodiments of the present disclosure are not limited thereto. For example, the first cover member 720 may be a cover window or a window cover, but exemplary embodiments of the present disclosure are not limited thereto.

At least one or more adhesive members may be disposed in the display area AA. For example, the at least one or more adhesive members may be disposed between the one or more cover members. For example, the at least one or more adhesive members may be disposed between the one or more cover members and disposed in the display area AA. The at least one or more adhesive members may include a lower adhesive layer (or a fourth adhesive member) 901 and an upper adhesive layer (or a fifth adhesive member) 903, but exemplary embodiments of the present disclosure are not limited thereto. For example, the lower adhesive layer (or the fourth adhesive member) 901 may be disposed between the encapsulation part 4000 and the polarization member 710. For example, the upper adhesive layer (or the fifth adhesive member) 903 may be disposed between the polarization member 710 and the first cover member 720. The lower adhesive layer (or the fourth adhesive member) 901 and the upper adhesive layer (or the fifth adhesive member) 903 may be configured by one of an optically cleared adhesive member (OCA), an optically cleared resin (OCR), and a pressure sensitive adhesive (PSA). The lower adhesive layer (or the fourth adhesive member) 901 may be a first adhesive member, but is not limited by the term. The upper adhesive layer (or the fifth adhesive member) 903 may be a second adhesive member, but is not limited by the term. For example, the first adhesive member may be the second adhesive member, the second adhesive member may be the first adhesive member, and the first adhesive member and the second adhesive member may be exchangeably used.

For example, when the first adhesive member 701, the second adhesive member 702, and the third adhesive member 703 are the third adhesive members, the lower adhesive layer (or the fourth adhesive member) 901 is the first adhesive member, and the upper adhesive layer (or the fifth adhesive member) 903 is the second adhesive member, at least one or more of the first adhesive member and the second adhesive member may be equal to at least one of the third adhesive member. For example, when the lower adhesive layer (or the fourth adhesive member) 901 is a first adhesive member and the upper adhesive layer (or the fifth adhesive member) 903 is a second adhesive member, at least one or more of the first adhesive member and the second adhesive member may be configured by the same material as one or more of the third adhesive members. For example, when the lower adhesive layer (or the fourth adhesive member) 901 is a second adhesive member and the upper adhesive layer (or the fifth adhesive member) 903 is a first adhesive member, at least one or more of the first adhesive member and the second adhesive member may be configured by the same material as one or more of the third adhesive members. For example, the first adhesive member 701, the second adhesive member 702, and the third adhesive member 703 are first adhesive members, the lower adhesive layer (or the fourth adhesive member) 901 is the second adhesive member, and the upper adhesive layer (or the fifth adhesive member) 903 is the third adhesive member, at least one or more first adhesive members may be configured with same material as at least one or more of the second adhesive member and the third adhesive member.

Referring to FIG. 6, a first layer 800 may be disposed on the first cover member 720. For example, the first cover member 720 may be configured by a thin cover glass (TCG). As another example, the first cover member 720 may be configured by two or more materials including a thin cover glass (TCG) and polyimide. The first layer 800 may be formed or coated by laminating a material including a material which reacts to the visible ray on the first cover member 720. When an external stimulation is applied to the first layer 800, contraction and/or expansion of the first layer 800 caused by the external stimulation may recover a portion of the folded portion or the variable area VA having marks or creases in the display apparatus.

For example, the first layer 800 may be configured by a photoreactive material. For example, the first layer 800 may include a photoreactive material or a polymer (or a polymer matrix). The first layer 800 may be formed of a shape memory material having a form memory effect in which a photoreactive material and a polymer (or a polymer matrix) are mixed. For example, the form memory effect may be a phenomenon in which even though an external force (or stimulation) is applied to a shape memorized in a polymer to transform it into a completely different shape, when memorized conditions are created, the shape may restore to its original shape.

For example, the polymer or polymer matrix of the first layer 800 may include acrylic polymer or epoxy polymer, but exemplary embodiments of the present disclosure are not limited thereto. For example, the polymer or polymer matrix of the first layer 800 may include polyethylene terephthalate, polyimide, polycarbonate, polymethylmethacrylate, and triacetylcellulose (TAC), but exemplary embodiments of the present disclosure are not limited thereto.

For example, the photoreactive material may be configured by a content of 5% to 20% (wt % or in weight percent) of the polymer matrix. For example, the photoreactive material may be included in the polymer matrix with a content of 5% to 20%. If the amount of the photoreactive material is less than 5% of the polymer matrix, it may be difficult to implement contraction and/or expansion. If the amount of the photoreactive material exceeds 20% of the polymer matrix, the physical properties of the polymer matrix, which is a base material, may deteriorate, making it difficult to realize desired reliability. The photoreactive material may be a material which reacts to the visible ray. For example, the photoreactive material may be a material which reacts light in a wavelength range of 365 nm to 500 nm. The photoreactive material may react through a photoisomerization reaction with light in a wavelength range of 365 nm to 500 nm, but exemplary embodiments of the present disclosure are not limited thereto. For example, when a functional group of a photoreactive material in a polymer is exposed to a specific wavelength range, it reacts and thus, the structure of molecules is changed to change a macroscopic property of the polymer material to recover the shape by means of the contraction and/or expansion.

For example, when the photoreactive material in the first layer 800 is exposed to a specific wavelength, photo reaction occurs. The photo reaction may include photoisomerization, photodimerization, and light induced cross-linking reaction, but exemplary embodiments of the present disclosure are not limited thereto. For example, the first layer 800 which reacts to the light by the photoisomerization may include azonenzene, axodibenaoic acid, and spirobenzopyran, but exemplary embodiments of the present disclosure are not limited thereto. For example, the first layer 800 which reacts to the light by the photodimerization may include coumarin derivatives and anthrancene, but exemplary embodiments of the present disclosure are not limited thereto. For example, the first layer 800 which reacts to the light by the cross linking may include coumarin derivatives and anthrancene, but exemplary embodiments of the present disclosure are not limited thereto.

According to the exemplary embodiment of the present disclosure, the photoreactive material included in the first layer 800 may be one of the following materials, but exemplary embodiments of the present disclosure are not limited thereto.

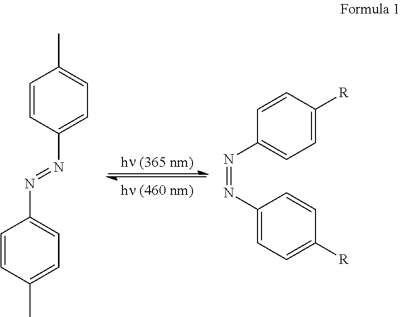

Formula 1 represents an azobenzene-based material which may reversibly react at a wavelength of 365 nm to 450 nm. The azobenzene-based material may be a light switch molecule and may have the property of changing its molecular structure by light. In the azobenzene-based material, the optically excited state of the atoms connecting the two benzene rings changes depending on a wavelength of light. Thus, a shape of a material including azobenzene-based material may be changed and the deformation in the folded portion of the display apparatus may be restored to its original state using this phenomenon.

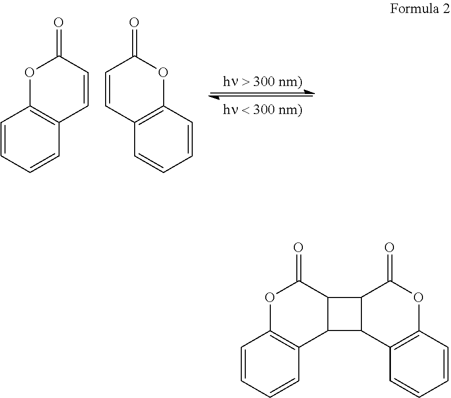

Formula 2 represents a coumarin-based material which may reversibly react in a wavelength of 300 nm or higher. The coumarin-based material may form a crosslinking by the light to change a shape of the material so that the deformation in the folded portion of the display apparatus may be restored to its original state.

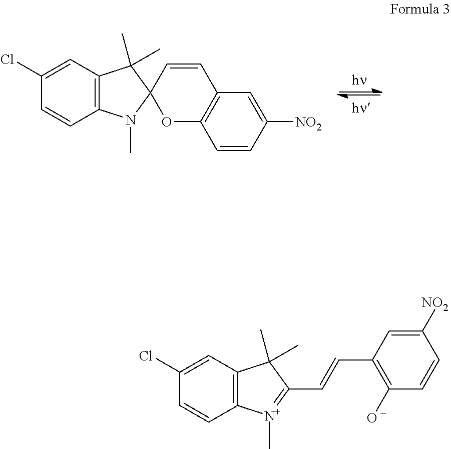 [SMILES: CN1c2ccc(Cl)cc2C(C)(C)C12C=Cc1cc([N+](=O)[O-])ccc1O2 ; C[N+]1=C(/C=C/c2cc([N+](=O)[O-])ccc2O)C(C)(C)c2cc(Cl)ccc21]

Formula 3 represents a spirobenzopyranbased material which may reversibly react in a wavelength of 435 nm. The spirobenzopyran-based material may change the shape of the material using a protonated state change. For example, when the spirobezopyran-based material is exposed to a specific wavelength, the molecules are protonated and the balance of hydrophobicity and/or hydrophilicity of the protonated molecule is changed. Thus, the contraction occurs to restore the deformation in the folded portion of the display apparatus to its original state.

According to an exemplary embodiment of the present disclosure, a restoration degree of the mark or crease in the folded portion of the display apparatus may be adjusted by adjusting a content ratio of the photoreactive material in the polymer of the first layer 800, adjusting the composition ratio of monomers and additives, adjusting a molecular weight of monomers and additives, and adding side chains to polymers.

For example, the first layer 800 may be configured of a material different from that of the at least one or more adhesive members, among the first adhesive member 701, the second adhesive member 702, and the third adhesive member 703. For example, the first layer 800 may be configured of a material different from the at least one or more adhesive members, among the lower adhesive member (or the fourth adhesive member) 901 and the upper adhesive member (or the fifth adhesive member) 903.

As another embodiment of the present disclosure, the first layer 800 may be disposed so as to correspond to the variable area VA. The first layer 800 formed of the photoreactive material is disposed in the variable area VA so that the deformation generated in the variable area VA may be improved.

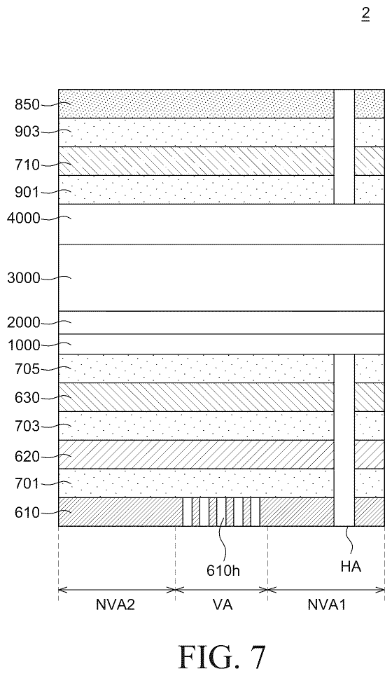

FIG. 7 illustrates a display apparatus according to another exemplary embodiment of the present disclosure.

Referring to FIG. 7, a display apparatus 2 according to another exemplary embodiment of the present disclosure may include a first layer 850. The other description excluding the first layer 850 is substantially the same as the description of FIG. 6 so that the description thereof may be omitted.

The first layer 850 according to another exemplary embodiment of the present disclosure may be disposed on the upper adhesive member (or the fifth adhesive member) 903. For example, the first layer 850 may be a film type integrally configured with the first cover member 720 of FIG. 6. The first layer is integrated as a film without using the adhesive or the adhesive member so that the weakened of the adhesive strength of the adhesive or the adhesive member or delamination of the adhesive or the adhesive member due to the folding may be improved. The first layer 850 may be a first film, but exemplary embodiments of the present disclosure are not limited thereto.

For example, the first layer 850 may be configured by a photoreactive material. For example, the first layer 850 may include a photoreactive material or a polymer (or a polymer matrix). The first layer 850 may be formed of a shape memory material in which a photoreactive material and a polymer (or a polymer matrix) are mixed. For example, the first layer 850 may be implemented such that the photoreactive material which reacts to the visible ray is exposed to the light to react to cause the contraction by the photo reaction. Thus, the polymer material may be configured by occurring a restoration.

For example, the photoreactive material of the first layer 850 may be configured with the material of Formulae 1 to 3, but exemplary embodiments of the present disclosure are not limited thereto.

The first layer 850 according to another exemplary embodiment of the present disclosure is configured as a film configured integrally with the first cover member 720 so that the first layer needs to have a function of the cover member. For example, when the first layer is configured with a polyimide film, rather than a thin cover glass (TCG), among the materials which configure the first cover member 720, the first layer 850 may be integrated with the first cover member 720 to be configured as a film. For example, the first layer 850 may be integrally configured with the first cover member 720 to be configured as one sheet of film. For example, the first layer 850 may be configured with the first cover member as a uni-material. Thus, the first layer 850 is configured as one film together with the first cover member 720 so that components which configure the display apparatus may be unified or simplified. For example, the first cover member 720, such as a polymer material (for example, polyimide) having a physical property which replace the cover glass and the first layer 850 which assists to implement the physical property of the cover glass are combined to configure one film. Thus, the first layer 850 may be configured to have rigidity and/or durability as compared with the first layer 800 of FIG. 6. For example, the polymer matrix of the first layer 850 may be polyimide, clear polyimide or colorless polyimide, and thermoplastic polyurethane, but exemplary embodiments of the present disclosure are not limited thereto.

For example, the photoreactive material may be configured by a content of 5% to 20% of the polymer matrix. For example, the photoreactive material may be included in the polymer matrix with a content of 5% to 20%. If the amount of the photoreactive material is less than 5% of the polymer matrix, it may be difficult to implement contraction and/or expansion. If the amount of the photoreactive material exceeds 20% of the polymer matrix, the physical properties of the polymer matrix, which is a base material, may deteriorate, making it difficult to realize desired reliability. The photoreactive material may be a material which reacts to the visible ray. For example, the photoreactive material may be a material which reacts light in a wavelength of 365 nm to 500 nm. The photoreactive material may react through a photoisomerization reaction with light in a wavelength range of 365 nm to 500 nm, but the exemplary embodiments of the present disclosure are not limited thereto. For example, when a functional group of a photoreactive material in a polymer is exposed to a specific wavelength range, it reacts and thus, the property of the polymer is changed and restore the shape by means of the contraction and/or expansion.

According to an exemplary embodiment of the present disclosure, a restoration degree of the mark or crease in the folded portion of the display apparatus may be adjusted by adjusting a content ratio of the photoreactive material in the polymer of the first layer 850, adjusting the composition ratio of monomers and additives, adjusting a molecular weight of monomers and additives, and adding side chains to polymers.

For example, the first layer 850 may be configured of a material different from that of the at least one or more adhesive members, among the first adhesive member 701, the second adhesive member 702, and the third adhesive member 703. For example, the first layer 850 may be configured of a material different from that of the at least one or more adhesive members, among the lower adhesive member (or the fourth adhesive member) 901 and the upper adhesive member (or the fifth adhesive member) 903.

As another embodiment of the present disclosure, the first layer 850 may be disposed so as to correspond to the variable area VA. The first layer 850 formed of a photoreactive material is disposed in the variable area VA to improve the deformation generated in the variable area VA.

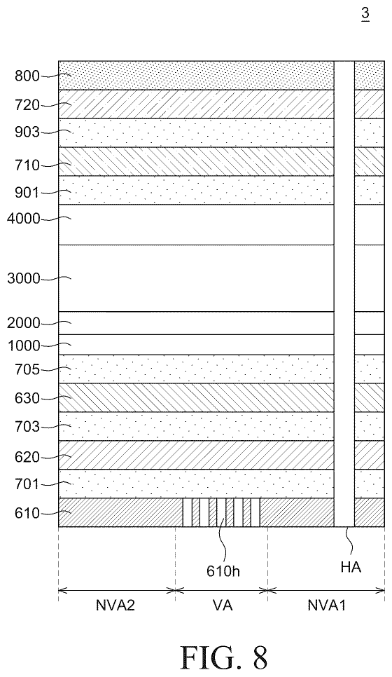

FIG. 8 illustrates a display apparatus according to another exemplary embodiment of the present disclosure.

FIG. 8 illustrates another example of the hole area HA in the display apparatus of FIG. 6. The description of FIG. 8 may be applied to FIG. 7 in the same way. For example, the hole area HA of FIG. 7 is applied to FIG. 7 in the same way.

A display apparatus 3 according to another exemplary embodiment of the present disclosure may include a hole area HA from a part of one or more plates to a part of one or more cover members. For example, the hole area HA may be disposed from a part of one or more plates of the first plate 610, the second plate 620, and the third plate 630 to a part of one or more cover members of the first cover member 720. For example, the hole area HA in one or more plates of the first plate 610, the second plate 620, and the third plate 630 may be an empty space. The hole area HA may be disposed in the transistor part 1000, the emission part 2000, the encapsulation part 3000, and the touch part 4000. For example, the hole area HA may be disposed in a part of one or more plates of the first plate 610, the second plate 620, and the third plate 630, the transistor part 1000, the emission part 2000, the encapsulation part 3000, and the touch part 4000, and a part of one or more cover members of the first cover member 720. For example, the hole area HA may be disposed in the first plate 610, the second plate 620, the third plate 630, the transistor part 1000, the emission part 2000, the encapsulation part 3000, the touch part 4000, the first cover member 720. The display apparatus 3 of FIG. 8 in which the hole area HA is disposed may be referred to as a hole in display (HID), but is not limited by the term. For example, in the hole area HA, at least one or more of a camera, a sensor, and an optical component are disposed, but exemplary embodiments of the present disclosure are not limited thereto. For example, the sensor may be an infrared sensor, but exemplary embodiments of the present disclosure are not limited thereto.

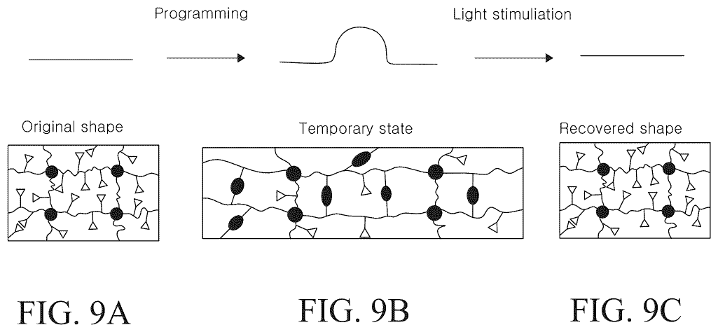

FIGS. 9A, 9B, and 9C illustrate a light reaction of a first layer according to another exemplary embodiment of the present disclosure.

FIG. 9A illustrates an original shape (for example, an original shape of the crystalline phase or crystalline structure) of the first layers 800 and 850 of FIGS. 6 to 8. For example, FIG. 9A illustrates a shape corresponding to the display apparatus of FIG. 5A before being folded.

An original shape of FIG. 9A may be changed to a temporary state of FIG. 9B by a programming which is a process of mixing a material reactive to light. For example, the programming may be based on a phase change in a specific stimulation. For example, the programming may be a phase change according to temperature or light applied from the outside. The programming according to an embodiment of the present disclosure may be a programming by light. The programming by light configures a shape of molecules or a material to a temporary state using a specific wavelength and changes the shape to a designed shape by irradiating light in a desired wavelength. For example, FIG. 9A illustrates a shape of corresponding to FIG. 5A before being folded. In the temporary shape of FIG. 9B, the photo stimulation is applied to the photoreactive material of the first layers 800 and 850 to have a recovered state which is recovered to the original shape as illustrated in FIG. 9C.

The first layers 800 and 850 according to an exemplary embodiment of the present disclosure may be configured by a shape memory material. For example, the shape memory material may include a photoreactive material and a polymer. The first layers 800 and 850 are configured by the shape memory material so that in FIG. 9A, an original shape having a predetermined shape is shown, and the folded portion is deformed as the display apparatus is folded and unfolded, as illustrated in FIG. 9B. When the light stimulation is applied to the first layers 800 and 850 which are photoreactive materials in response to the deformation of the folded portion, it may be recovered to its original shape as illustrated in FIG. 9C.

For example, the first layers 800 and 850 include a material which reacts to the light corresponding to a specific wavelength range so that the first layers may be recovered to its original shape by the light stimulation, thereby the marks or creases in the folded portion of the display apparatus may be improved. For example, to improve the marks or creases in the folded portion of the display apparatus, a material of the first layers 800 and 850 which reacts to the light reacts to cause contraction and/or expansion of the first layers 800 and 850. Thus, the marks or creases in the folded portion of the display apparatus may be improved.

A display apparatus according to an exemplary embodiment of the present disclosure may be applicable to or included in a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic book, a portable multimedia player (PMP), a personal digital assistant (PDA), an MP3 player, a mobile medical apparatus, a desktop PC, a laptop PC, a netbook computer, a workstation, a navigation, a navigation for a vehicle, a display apparatus for a vehicle, an apparatus for a vehicle, a theatrical device, a theatrical display, a television, a wallpaper device, a signage device, a game device, a notebook, a monitor, a camera, a camcorder, and a consumer electronics device. Further, the display apparatus of the present disclosure is also applied to or included in an organic light emitting illumination device or an inorganic light emitting illumination device.

A display apparatus according to exemplary embodiments of the present disclosure can be described as follows.

A display apparatus according to one or more embodiments of the present disclosure may comprise a display panel including a variable area and a non-variable area, a first adhesive member disposed on the display panel and a first layer disposed on the first adhesive member, a material of the first layer being different from a material of the first adhesive member. The first layer may include a photoreactive material.

According to one or more embodiments of the present disclosure, the variable may include foldable, bendable or flexible.

According to one or more embodiments of the present disclosure, the first layer may be formed of a shape memory material in which a photoreactive material and a polymer are mixed.

According to one or more embodiments of the present disclosure, the photoreactive material may be a material which reacts to the visible ray.

According to one or more embodiments of the present disclosure, the first layer may further include a polymer, and the photoreactive material may have a content of 5% to 20% of the polymer.

According to one or more embodiments of the present disclosure, the photoreactive material may include a material which reacts by photo isomerization in a wavelength range of 350 nm to 500 nm.

According to one or more embodiments of the present disclosure, the first adhesive member may include one of an optically cleared adhesive, an optically cleared resin, and a pressure sensitive adhesive.

According to one or more embodiments of the present disclosure, the photoreactive material included in the first layer may include an azobenzene-based material, a coumarin-based material, or a spirobenzopyran-based material

According to one or more embodiments of the present disclosure, the first layer may be disposed so as to correspond to the variable area.

According to one or more embodiments of the present disclosure, the display apparatus may further include a first cover member on the first adhesive member. The first layer may be disposed on the first cover member.

According to one or more embodiments of the present disclosure, the first layer may be a film integrally configured with the first cover member.

According to one or more embodiments of the present disclosure, the display apparatus may further include a polarization member below the first cover member and a second adhesive member between the polarization member and the first cover member.

According to one or more embodiments of the present disclosure, the second adhesive member may include a material different from that of the first layer.

According to one or more embodiments of the present disclosure, the second adhesive member may include one of an optically cleared adhesive, an optically cleared resin, and a pressure sensitive adhesive.

According to one or more embodiments of the present disclosure, the display apparatus may further include one or more plates below the display panel and one or more third adhesive members between the one or more plates. One or more third adhesive members between adjacent plates of two or more plates among the one or more plates.

According to one or more embodiments of the present disclosure, at least one of the one or more plates may further include one or more opening patterns.

According to one or more embodiments of the present disclosure, the one or more opening patterns may be disposed to correspond to the variable area.

According to one or more embodiments of the present disclosure, the variable area may be foldable with respect to a folding axis. The one or more opening patterns may extend in a direction parallel to the folding axis and/or may be configured in a discontinuous shape.

According to one or more embodiments of the present disclosure, the one or more opening patterns may include two or more opening patterns. The two or more opening patterns may be configured in different shapes or with different intervals in the variable area.

According to one or more embodiments of the present disclosure, the one or more third adhesive members may include a material different from that of the first layer.

According to one or more embodiments of the present disclosure, the one or more third adhesive members may include one of an optically cleared adhesive, an optically cleared resin, and a pressure sensitive adhesive.

According to one or more embodiments of the present disclosure, the display panel may further include a hole area. The hole area may be disposed in a part of the one or more plates and a part of the first cover member.

According to one or more embodiments of the present disclosure, one or more of a camera, a sensor, and an optical component may be disposed in the hole area.

According to one or more embodiments of the present disclosure, the display panel may include a transistor part and an emission part, and the display apparatus may further include an encapsulation part on the emission part and a touch part on the encapsulation part.

According to one or more embodiments of the present disclosure, the display panel may further include a hole area. The hole area may be disposed in a part of at least one of the one or more plates, the transistor part, the emission part, the encapsulation part, the touch part, and the first cover member.

According to one or more embodiments of the present disclosure, one or more of a camera, a sensor, and an optical component may be disposed in the hole area.

A display apparatus according to some embodiments of the present disclosure may comprise a display panel including a variable area and a non-variable area, a first layer disposed adjacent to the display panel, one or more plates below the display panel, and a first adhesive member adjacent to the one or more plates. The first layer and the first adhesive member may be configured by different materials.

According to one or more embodiments of the present disclosure, the first layer may include a material which reacts to the visible ray. The first adhesive member may include one of an optically cleared adhesive, an optically cleared resin, and a pressure sensitive adhesive.

According to one or more embodiments of the present disclosure, the first layer may further include a polymer. The material which reacts to the visible ray and the polymer constitute a shape memory material.

According to one or more embodiments of the present disclosure, the material which reacts to the visible ray may have a content of 5% to 20% of the polymer.

It will be apparent to those skilled in the art that various modifications and variations can be made in the present disclosure without departing from the scope of the present disclosure. Thus, it is intended that the present disclosure covers the modifications and variations of this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display apparatus, comprising:
a display panel including a variable area and a non-variable area;
a first adhesive member disposed on the display panel; and
a first layer disposed on the first adhesive member, a material of the first layer being different from a material of the first adhesive member,
wherein the first layer includes a photoreactive material.

2. The display apparatus of claim 1, wherein the first layer is formed of a shape memory material in which a photoreactive material and a polymer are mixed.

3. The display apparatus of claim 1, wherein the photoreactive material is a material which reacts to the visible ray.

4. The display apparatus of claim 1, wherein the first layer further includes a polymer, and the photoreactive material has a content of 5% to 20% of the polymer.

5. The display apparatus of claim 1, wherein the photoreactive material includes a material which reacts by photo isomerization in a wavelength range of 350 nm to 500 nm.

6. The display apparatus of claim 1, wherein the photoreactive material included in the first layer include an azobenzene-based material, a coumarin-based material, or a spirobenzopyran-based material.

7. The display apparatus of claim 1, wherein the first layer is disposed so as to correspond to the variable area.

8. The display apparatus of claim 1, wherein the first adhesive member includes one of an optically cleared adhesive, an optically cleared resin, and a pressure sensitive adhesive.

9. The display apparatus of claim 1, further comprising a first cover member on the first adhesive member,
wherein the first layer is disposed on the first cover member.

10. The display apparatus of claim 9, wherein the first layer is a film integrally configured with the first cover member.

11. The display apparatus of claim 9, further comprising:
a polarization member below the first cover member; and
a second adhesive member between the polarization member and the first cover member.

12. The display apparatus of claim 11, wherein the second adhesive member includes a material different from that of the first layer.

13. The display apparatus of claim 12, wherein the second adhesive member includes one of an optically cleared adhesive, an optically cleared resin, and a pressure sensitive adhesive.

14. The display apparatus of claim 9, further comprising:
one or more plates below the display panel; and
one or more third adhesive members between the one or more plates.

15. The display apparatus of claim 14, wherein at least one of the one or more plates further includes one or more opening patterns.

16. The display apparatus of claim 15, wherein the one or more opening patterns are disposed to correspond to the variable area.

17. The display apparatus of claim 16, wherein:
the variable area is foldable with respect to a folding axis; and
the one or more opening patterns extend in a direction parallel to the folding axis and/or are configured in a discontinuous shape.

18. The display apparatus of claim 17, wherein the one or more opening patterns includes two or more opening patterns, and the two or more opening patterns are configured in different shapes or with different intervals in the variable area.

19. The display apparatus of claim 14, wherein the one or more third adhesive members include a material different from that of the first layer.

20. The display apparatus of claim 19, wherein the one or more third adhesive members include one of an optically cleared adhesive, an optically cleared resin, and a pressure sensitive adhesive.

21. The display apparatus of claim 14, wherein the display panel further includes a hole area, and
wherein the hole area is disposed in a part of the one or more plates and a part of the first cover member.

22. The display apparatus of claim 21, wherein one or more of a camera, a sensor, and an optical component are disposed in the hole area.

23. The display apparatus of claim 14, wherein the display panel includes a transistor part and an emission part, and
wherein the display apparatus further comprises:
an encapsulation part on the emission part; and
a touch part on the encapsulation part.

24. The display apparatus of claim 23, wherein the display panel further includes a hole area, and
wherein the hole area is disposed in a part of at least one of the one or more plates, the transistor part, the emission part, the encapsulation part, the touch part, and the first cover member.

25. The display apparatus of claim 24, wherein one or more of a camera, a sensor, and an optical component are disposed in the hole area.

26. A display apparatus, comprising:
a display panel including a variable area and a non-variable area;
a first layer disposed adjacent to the display panel;
one or more plates below the display panel; and
a first adhesive member adjacent to the one or more plates,
wherein the first layer and the first adhesive member are configured by different materials.

27. The display apparatus of claim 26, wherein the first layer includes a material which reacts to the visible ray, and
wherein the first adhesive member includes one of an optically cleared adhesive, an optically cleared resin, and a pressure sensitive adhesive.

28. The display apparatus of claim 27, wherein the first layer further includes a polymer, and
wherein the material which reacts to the visible ray and the polymer configure a shape memory material.

29. The display apparatus of claim 28, wherein the material which reacts to the visible ray has a content of 5% to 20% of the polymer.
